(19) United States
(12) Patent Application Publication
(10) Pub. No.: US 2025/0366283 A1
(43) Pub. Date: Nov. 27, 2025

(54) SEMICONDUCTOR COMPONENT AND SEMICONDUCTOR DEVICE

(71) Applicant: Lextar Electronics Corporation, Hsinchu City (TW)

(72) Inventors: Shiou-Yi KUO, Hsinchu City (TW); Tsung-Hao SU, Hsinchu City (TW); Shun-Hong WANG, Hsinchu City (TW); Wei-Yuan MA, Hsinchu City (TW)

(21) Appl. No.: 19/189,091

(22) Filed: Apr. 24, 2025

(30) Foreign Application Priority Data
May 22, 2024 (TW) 113118889

(51) Int. Cl. H10H 29/03; H10H 29/852

(52) U.S. Cl. CPC H10H 29/03; H10H 29/852

(57) ABSTRACT

A semiconductor component and a semiconductor device are provided. The semiconductor component includes a carrier, a semiconductor element, and a protective layer. The carrier includes a substrate and a bracket structure. The bracket structure is disposed on the substrate. The semiconductor element is disposed on the carrier. The semiconductor element includes a semiconductor stack, a plurality of electrodes, and a roughened structure. The semiconductor stack has a first surface and a second surface, which are opposite each other. The electrodes are disposed on the first surface. The roughened structure is disposed on the second surface and is in direct contact with the bracket structure. The protective layer is disposed on the first surface and covers the electrodes.

### CROSS REFERENCE TO RELATED APPLICATIONS

This application claims priority of Taiwan Patent Application No. 113118889, filed on May 22, 2024, and the content of the entirety of which is incorporated by reference herein.

### BACKGROUND OF THE DISCLOSURE

### Field of the Disclosure

The present disclosure relates to semiconductor technology, and, in particular, to a semiconductor component and a semiconductor device.

### Description of the Related Art

As the size of semiconductor devices gradually scaling down, the number of semiconductor elements in semiconductor devices increases rapidly, which poses a serious challenge to the manufacturing process. Among them, a mass transfer process can be used to transfer these semiconductor elements from the growth substrate to the carrier or from the carrier to the circuit board, so that the semiconductor elements can be processed more easily. Although existing semiconductor devices and their manufacturing processes are gradually meeting their intended uses, they do not meet the requirements in all aspects. Therefore, there are still some problems that need to be overcome regarding semiconductor devices and their manufacturing processes.

### BRIEF SUMMARY OF THE DISCLOSURE

In some embodiments, a semiconductor component is provided. The semiconductor component includes a carrier, a semiconductor element, and a protective layer. The carrier includes a substrate and a bracket structure. The bracket structure is disposed on the substrate. The semiconductor element is disposed on the carrier. The semiconductor element includes a semiconductor stack, a plurality of electrodes, and a roughened structure. The semiconductor stack has a first surface and a second surface, which are opposite each other. The electrodes are disposed on the first surface. The roughened structure is disposed on the second surface and is in direct contact with the bracket structure. The protective layer is disposed on the first surface and covers the electrodes.

In some embodiments, a semiconductor device is provided. The semiconductor device includes an electrical connection component, a semiconductor element, an insulating layer, and a light-transmitting layer. The semiconductor element is disposed on the electrical connection component, wherein the semiconductor element includes a semiconductor stack, a plurality of electrodes, and a roughened structure. The semiconductor stack has a first surface and a second surface, which are opposite each other. The first surface faces the electrical connection component. The electrodes are disposed on the first surface and electrically connected to the electrical connection component. The roughened structure is disposed on the second surface. The insulating layer covers the semiconductor element and the electrical connection component, and exposes the roughened structure of the semiconductor element and a joint surface of the electrical connection component. The light-transmitting layer is disposed on the insulating layer and covers the insulating layer and the exposed roughened structure.

The device of the present disclosure may be applied in a variety of electronic devices. In order to make the features and advantages of the present disclosure more comprehensible, various embodiments are specially cited hereinafter, together with the accompanying drawings, to be described in detail as follows.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1 to 6 are cross-sectional views of the semiconductor component at different stages in the forming method according to some embodiments of the present disclosure.

FIGS. 7 to 9 are cross-sectional views of the semiconductor device at different stages in the forming method according to some embodiments of the present disclosure.

FIG. 10 is an enlarged schematic view of the area A of FIG. 9.

FIG. 11 is a cross-sectional view of the semiconductor device at different stages in the forming method according to some embodiments of the present disclosure.

FIG. 12 is an enlarged schematic view of the area A′ of FIG. 11.

FIG. 13 is a cross-sectional view of the semiconductor device at different stages in the forming method according to some embodiments of the present disclosure.

### DETAILED DESCRIPTION OF THE INVENTION

The devices of various embodiments of the present disclosure will be described in detail below. It should be understood that the following description provides many different embodiments for implementing various aspects of some embodiments of the present disclosure. The specific elements and arrangements described below are merely to clearly describe some embodiments of the present disclosure. Of course, these are only used as examples rather than limitations of the present disclosure. Furthermore, similar or corresponding reference numerals may be used in different embodiments to designate similar or corresponding elements in order to clearly describe the present disclosure. However, the use of these similar or corresponding reference numerals is only for the purpose of simply and clearly description of some embodiments of the present disclosure, and does not imply any correlation between the different embodiments or structures discussed.

In some embodiments of the present disclosure, terms related to bonding and connection, such as “connect”, “interconnect”, “bond”, and the like, unless otherwise defined, may refer to two features in direct contact, or may also refer to two features not in direct contact, that is there is another feature disposed between the two features. Moreover, the terms related to bonding and connection may also include embodiments in which both features are movable, or both features are fixed.

In addition, it should be understood that ordinal numbers such as “first”, “second”, and the like used in the description and claims are used to modify elements and are not intended to imply and represent the element(s) have any previous ordinal numbers, and do not represent the order of a certain element and another element, or the order of the manufacturing method.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” may still be implied without the specific description of “approximately”, “about”, and “substantially”. The phrase “a range between a first value and a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Unless otherwise defined, all terms (including technical and scientific terms) used herein have the same meaning as commonly understood by a person of ordinary skills in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

It should be understood that, for clarity of explanation, some elements of the device are omitted in the drawings, and only some elements are schematically illustrated. In some embodiments, additional components may be added to the devices described below. In other embodiments, some components of the device described below may be replaced or omitted. It should be understood that, in some embodiments, additional operational steps may be provided before, during, and/or after the forming method of the device. In some embodiments, some of the steps described may be replaced or omitted, and the order of some of the steps described is interchangeable.

The present disclosure provides a roughened structure and a fiber bracket on the contact surface between the semiconductor element and the carrier for improving connection stability, thereby reducing the risks of the semiconductor element not being stably fixed on the carrier due to the contact surface being too smooth.

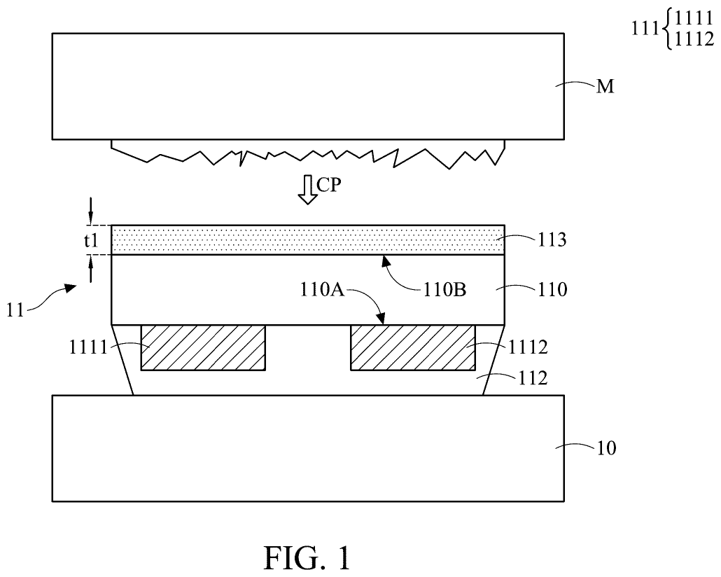

FIGS. 1 to 6 are cross-sectional views of the semiconductor component at different stages of the forming method according to some embodiments of the present disclosure. To simplify the drawing, only a single semiconductor element 11 is shown here for clarity of explanation. In other embodiments, there may be a plurality of semiconductor elements 11. As shown in FIG. 1, a first substrate 10 is provided, which may be used to carry a semiconductor element 11 located thereon. In some embodiments, the first substrate 10 may include conductive material or non-conductive material. For example, the conductor material may include silicon (Si), silicon carbide (SiC), gallium nitride (GaN), aluminum gallium nitride (AlGaN), aluminum nitride (AlN), gallium phosphide (GaP), gallium arsenide (GaAs), aluminum gallium arsenide (AlGaAs), other suitable materials, or a combination thereof, but the present disclosure is not limited thereto. The non-conductor materials may include glass, quartz, sapphire, diamond (C), ceramic, polyimide (PI), polycarbonate (PC), polyethylene terephthalate (PET), polypropylene (PP), other suitable materials, or a combination thereof, but the present disclosure is not limited thereto.

As shown in FIG. 1, the semiconductor element 11 is disposed on the first substrate 10. In some embodiments, the semiconductor element 11 may be fixed on the first substrate 10 through an adhesive layer (not shown). For example, an adhesive layer may be provided on the first substrate 10 first, and then the semiconductor element 11 is fixed on the first substrate 10. Alternatively, an adhesive layer may be provided on the semiconductor element 11 first, and then the semiconductor element 11 is fixed on the first substrate 10. In some embodiments, the adhesive layer may be or include thermal release glue, UV release glue, a combination thereof, or other suitable materials, but the present disclosure is not limited thereto.

In some embodiments, the semiconductor element 11 may include a light-emitting diode, a laser diode, a photodiode, a photo detector, an integrated circuit (IC), other suitable semiconductor elements, or a combination thereof, but the present disclosure is not limited thereto.

In some embodiments, the semiconductor element 11 may include a semiconductor stack 110, a plurality of electrodes 111, a protective layer 112, and a roughened material layer 113. In embodiments in which the semiconductor element 11 is a micro light-emitting diode, the semiconductor stack 110 may include a first semiconductor layer, a light-emitting layer, and a second semiconductor layer, which are stacked in sequence. In some embodiments, the first semiconductor layer, the light-emitting layer, and the second semiconductor layer may be formed through an epitaxial growth process, but the present disclosure is not limited thereto. In some embodiments, the first semiconductor layer may be a P-type semiconductor layer, and the second semiconductor layer may be an N-type semiconductor layer. In other embodiments, the conductivity types of the first semiconductor layer and the second semiconductor layer may be interchanged.

In some embodiments, the semiconductor stack 110 may include Group II-VI materials or Group III-V materials. For example, Group II-VI materials may include zinc selenide (ZnSe). For example, Group III-V materials may include gallium nitride (GaN), aluminum nitride (AlN), indium nitride (InN), indium gallium nitride (InGaN), aluminum gallium nitride (AlGaN), aluminum indium gallium nitride (AlInGaN), the like, or a combination thereof, but the present disclosure is not limited thereto. In some embodiments, the light-emitting layer may include single quantum well (QW) or multiple quantum wells (MQWs). In some embodiments, the P-type semiconductor layer may include a dopant such as magnesium (Mg) or carbon (C), but the present disclosure is not limited thereto. In some embodiments, the N-type semiconductor layer may include a dopant such as silicon (Si) or germanium (Ge), but the present disclosure is not limited thereto.

In some embodiments, the semiconductor stack 110 has a first surface 110A and a second surface 110B that are opposite to each other, and the electrodes 111 are disposed on the first surface 110A of the semiconductor stack 110. In some embodiments, the electrodes 111 may include a first electrode 1111 and a second electrode 1112, and the first electrode 1111 and the second electrode 1112 may be electrically connected to the semiconductor stack 110. Specifically, the first electrode 1111 may be electrically connected to the first semiconductor layer, and the second electrode 1112 may be electrically connected to the second semiconductor layer. In some embodiments, the first electrode 1111 and the second electrode 1112 may include conductive materials. For example, the conductive material may include metal, conductive compounds, other suitable conductive materials, or a combination thereof, but the present disclosure is not limited thereto. In some embodiments, the metal may be tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (AI), molybdenum (Mo), magnesium (Mg), zinc (Zn), alloys thereof, or a combination thereof, but the present disclosure is not limited thereto. In some embodiments, the conductive compound may include indium tin oxide (ITO), antimony zinc oxide (AZO), tin oxide (SnO), zinc oxide (ZnO), indium zinc oxide (IZO), indium gallium zinc oxide (IGZO), indium tin zinc oxide (ITZO), antimony tin oxide (ATO), titanic nitride (TIN), other suitable conductive compounds, or a combination thereof, but the present disclosure is not limited thereto. In some embodiments, the first electrode 1111 and the second electrode 1112 may be formed by electroplating, chemical vapor deposition, sputtering, resistance heating evaporation, electron beam evaporation, atomic layer deposition (ALD), other suitable formation processes, or a combination thereof, but the present disclosure is not limited thereto.

In some embodiments, the protective layer 112 is disposed on the first surface 110A of the semiconductor stack 110 and covers the electrodes 111. In some embodiments, the protective layer 112 may include polymer materials, other suitable materials, or a combination thereof, but the present disclosure is not limited thereto. For example, the polymer material may include epoxy, polyimide (PI), polypropylene (PP), other suitable polymer materials, or a combination thereof, but the present disclosure is not limited thereto. In some embodiments, the protective layer 112 has a trapezoidal shape in the cross-sectional view, but the present disclosure is not limited thereto. In other embodiments, in the cross-sectional view, the protective layer 112 may also be in a rectangular shape, a polygonal shape, or other suitable shapes.

In some embodiments, the roughened material layer 113 is disposed on the second surface 110B of the semiconductor stack 110, which is used to form the roughened structure 114 in subsequent steps. In some embodiments, the roughened material layer 113 may partially or completely cover the second surface 110B of the semiconductor stack 110. In some embodiments, the thickness t1 of the roughened material layer 113 may be between 100 nm and 1000 nm, but the present disclosure is not limited thereto. For example, the thickness t1 of the roughened material layer 113 may be 100 nm, 200 nm, 300 nm, 400 nm, 500 nm, 600 nm, 700 nm, 800 nm, 900 nm, 1000 nm, or any value or range between the above values. When the thickness t1 of the roughened material layer 113 is less than 100 nm, the roughened material layer 113 may be too thin to form the roughened structure 114. On the contrary, when the thickness t1 of the roughened material layer 113 is greater than 1000 nm, the subsequently formed roughened structure 114 may be too thick and hinder the operation (e.g., light emission) of the semiconductor element 11.

In some embodiments, the roughened material layer 113 may include metal materials, polymer materials, other suitable materials, or a combination thereof, but the present disclosure is not limited thereto. For example, the roughened material layer 113 may include tin (Sn). It should be noted that when the semiconductor element 11 is a light-emitting element, the roughened structure 114 (which is further described below) formed by the roughened material layer 113 must be penetrated by the light emitted by the light-emitting element. In other words, in this case, the roughened material layer 113 and the roughened structure 114 formed from which may include a light-transmitting material or may have a thickness so as to be light-transmitting.

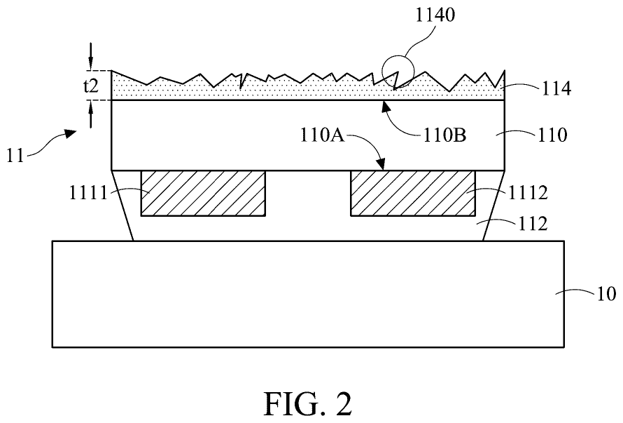

As shown in FIGS. 1 and 2, following the above steps, the roughening process CP is performed on the semiconductor element 11 so that the roughened material layer 113 forms the roughened structure 114. For example, the roughening process CP may be or include imprinting, thermal transfer printing, other suitable roughening processes, or a combination thereof, but the present disclosure is not limited thereto. For example, the thermal transfer may be performed on the roughened material layer 113 of the semiconductor element 11 by the mold M with sharp protrusions to form the roughened structure 114.

In some embodiments, the thickness t2 of the roughened structure 114 may be similar or the same as the thickness t1 of the roughened material layer 113, but the present disclosure is not limited thereto. For example, the thickness t2 of the roughened structure 114 may be slightly less than the thickness t1 of the roughened material layer 113. In some embodiments, the thickness t2 of the roughened structure 114 may be between 100 nm and 1000 nm, but the present disclosure is not limited thereto. For example, the thickness t2 of the roughened structure 114 may be 100 nm, 200 nm, 300 nm, 400 nm, 500 nm, 600 nm, 700 nm, 800 nm, 900 nm, 1000 nm, or any value or range between the above values. When the thickness t2 of the roughened structure 114 is less than 100 nm, the roughened structure 114 may be too thin to be firmly connected to the bracket structure (which is further described below). On the contrary, when the thickness t2 of the roughened structure 114 is greater than 1000 nm, the roughened structure 114 may be too thick and hinder the operation (e.g., light emission) of the semiconductor element 11.

In some embodiments, the roughened structure 114 may include a plurality of sharp protrusions 1140, and these sharp protrusions 1140 protrude in a direction away from the second surface 110B. In some embodiments, the sharp protrusions 1140 include a plurality of hooks, such as inwardly curled barbs or sharp hooks extending sideways, but the present disclosure is not limited thereto. By forming the roughened structure 114 with the above characteristics, the semiconductor element 11 may be effectively attached to the carrier 12 (which is further described below) during the transfer process.

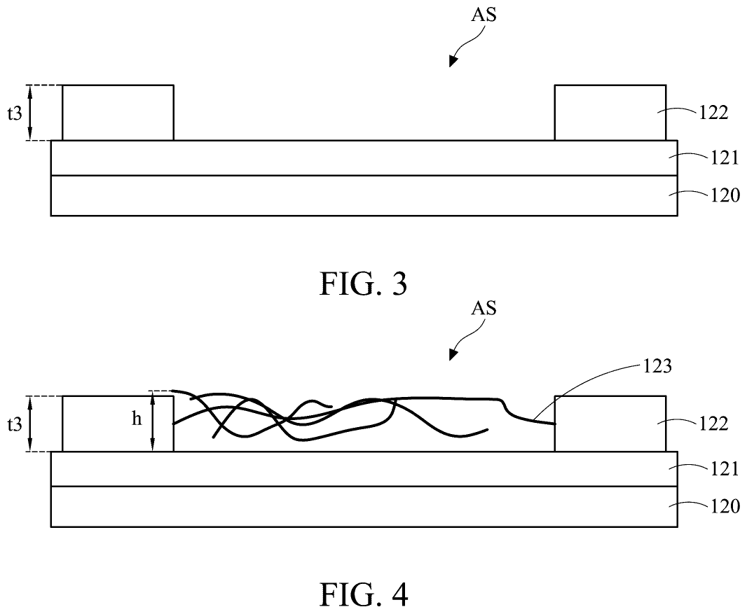

Referring to FIGS. 3 to 6, as shown in FIG. 3, a second substrate 120 is provided, which may be used to carry the bracket structure 123 located thereon (as shown in FIG. 4). In some embodiments, the second substrate 120 may include conductive materials or non-conductive materials. For example, the conductor materials may include silicon (Si), silicon carbide (SiC), gallium nitride (GaN), aluminum gallium nitride (AlGaN), aluminum nitride (AlN), gallium phosphide (GaP), gallium arsenide (GaAs), aluminum gallium arsenide (AlGaAs), other suitable materials, or a combination thereof, but the present disclosure is not limited thereto. The non-conductive materials may include diamond (C), glass, quartz, sapphire, ceramic, polyimide (PI), polycarbonate (PC), polyethylene terephthalate (PET), polypropylene (PP), other suitable materials, or a combination thereof, but the present disclosure is not limited thereto. In some embodiments, the material of the second substrate 120 may be similar or the same as the material of the first substrate 10, but the present disclosure is not limited thereto.

As shown in FIG. 3, following the above steps, the adhesive layer 121 is disposed on the second substrate 120. In some embodiments, the adhesive layer 121 may be a release layer, such as pyrolytic glue, photolytic glue, a combination thereof, or other suitable materials, but the present disclosure is not limited thereto. By providing the adhesive layer 121 that may be decomposed by heating or light, the second substrate 120 may be effectively removed in subsequent processes. In some embodiments, a spin coating process may be used to coat the adhesive layer 121 on the second substrate 120.

As shown in FIG. 3, following the above steps, a photoresist layer 122 is disposed on the adhesive layer 121, and the photoresist layer 122 is arranged to define an accommodation space AS. In some embodiments, in a top view, the photoresist layer 122 may be arranged with an enclosed shape to form the accommodating space AS of a circle, a triangle, a rectangle, a trapezoid, a star, other polygons, other suitable shapes, or a combination thereof, but the present disclosure is not limited thereto. In some embodiments, the photoresist layer 122 has a uniform thickness (i.e., a single thickness).

In some embodiments, the thickness t3 of the photoresist layer 122 may be between 100 nm and 2000 nm, but the present disclosure is not limited thereto. For example, the thickness t3 of the photoresist layer 122 may be 100 nm, 400 nm, 600 nm, 800 nm, 1000 nm, 1200 nm, 1400 nm, 1600 nm, 1800 nm, 2000 nm, or any value or range between the above values. When the thickness t3 of the photoresist layer 122 is less than 100 nm, the photoresist layer 122 may be too thin to prevent the bracket structure 123 (or its precursor) from overflowing. When the thickness t3 of the photoresist layer 122 is greater than 2000 nm, the photoresist layer 122 may be too thick thereby requiring excessive bracket structure 123 or cover layer 124 to be filled in the accommodation space A S. In some embodiments, a spin coating process may be used to form the photoresist layer 122 on the adhesive layer 121, and photolithography technology may be used to pattern the photoresist layer 122 (e.g., forming an enclosed shape to define the accommodating space A S).

As shown in FIG. 4, following the above steps, the bracket structure 123 is disposed in the accommodation space A S of the photoresist layer 122, which may be used to interconnect with the roughened structure 114 of the semiconductor element 11. In some embodiments, the material of the bracket structure 123 may include biodegradable polymer, but the present disclosure is not limited thereto. For example, the biodegradable polymer may include polyglycolic acid (PGA), poly-L-lactic acid (PLLA), poly(lactic-co-glycolic acid (PLGA), other suitable polymers, or a combination thereof, but the present disclosure is not limited thereto. In some embodiments, a precursor of the above material may be disposed in the accommodation space AS by spin coating, other suitable methods, or a combination thereof. The precursor is then polymerized to form the above-mentioned materials. By using biodegradable polymer, the environmental protection effect of the semiconductor device of the present disclosure may be effectively improved. In some embodiments, the shape of the bracket structure 123 may include fiber shape, a chain shape, or a combination thereof. These specific shapes are used to connect with the roughened structure 114 (e.g., hook each other).

In some embodiments, the bracket structure 123 may be completely located inside the accommodation space A S, that is, the bracket structure 123 does not protrude from the photoresist layer 122. For example, in the vertical direction, the maximum height h of the bracket structure 123 is less than or equal to the thickness t3 of the photoresist layer 122, but the present disclosure is not limited thereto. In some embodiments, the bracket structure 123 may be partially located in the accommodation space AS, that is, the bracket structure 123 protrudes from the photoresist layer 122. For example, in the vertical direction, the maximum height h of the bracket structure 123 is greater than the thickness t3 of the photoresist layer 122, but the present disclosure is not limited thereto.

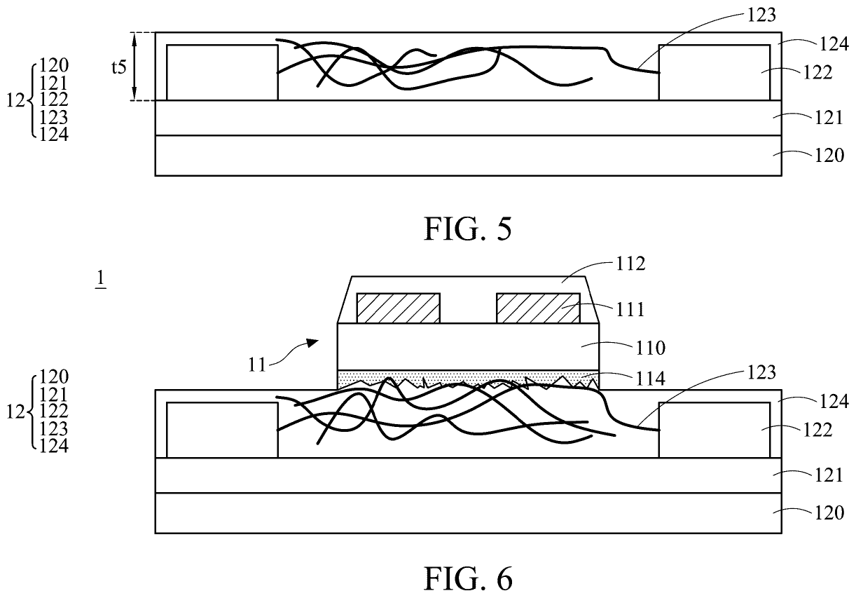

As shown in FIG. 5, following the above steps, a cover layer 124 is disposed on the bracket structure 123. Specifically, the cover layer 124 is disposed on the second substrate 120 and covers the adhesive layer 121, the bracket structure 123, and the photoresist layer 122. The cover layer 124 may be used to prevent the bracket structure 123 from detaching from the surface of the adhesive layer 121. In addition, the cover layer 124 may also be used to protect the bracket structure 123 from being corroded or contaminated by moisture, dust, or other impurities from the outside. Therefore, in some embodiments, the cover layer 124 may completely cover bracket structure 123.

In some embodiments, the cover layer 124 may include dielectric materials, other suitable materials, or a combination thereof, but the present disclosure is not limited thereto. For example, the cover layer 124 may be silicone or the like. In some embodiments, the cover layer 124 may include a material with less hardness than the roughened structure 114 so that the roughened structure 114 may penetrate the cover layer 124 and connect with the bracket structure 123.

In some embodiments, the second substrate 120, the adhesive layer 121, the photoresist layer 122, the bracket structure 123, and the cover layer 124 may be collectively referred to as the carrier 12.

As shown in FIG. 6, following the above steps, the semiconductor element 11 located on the first substrate 10 is transferred to the carrier 12. Specifically, after the semiconductor element 11 in FIG. 2 is turned over and the roughened structure 114 is aligned with the bracket structure 123 of the carrier 12, a transfer process is used to separate the semiconductor element 11 from the first substrate 10. The semiconductor element 11 on the first substrate 10 falls to the carrier 12 due to gravity, and the roughened structure 114 may penetrate the cover layer 124 and be in direct contact with the bracket structure 123 to join each other. The transfer process may include laser, irradiation, heating, or other suitable methods to separate the semiconductor element 11 from the first substrate 10 and to expose the protective layer 112 of the semiconductor element 11. After completing the above steps, the semiconductor component 1 is obtained, and the semiconductor component 1 includes the carrier 12 and the semiconductor element 11 disposed on the carrier 12.

In some embodiments, the aforementioned semiconductor component 1 may continue to be used in a forming method of a semiconductor device. In other words, the semiconductor component 1 may be an intermediate structure in a forming method of a semiconductor device. It should be noted that the semiconductor component 1 of the present disclosure is not limited to the elements or components mentioned above or shown in the drawings. In other embodiments, the semiconductor component 1 of the present disclosure may also include elements or components known to a person having ordinary skill in the art.

In the present disclosure, since the roughened structure 114 has the sharp protrusions 1140 and the bracket structure 123 has a fibrous or chain-like structure, the roughened structure 114 and the bracket structure 123 may be arranged in a manner of hook and loop fastener to connected to each other. In this case, the semiconductor element 11 may be stably disposed on the carrier 12, thereby greatly improving the transfer yield.

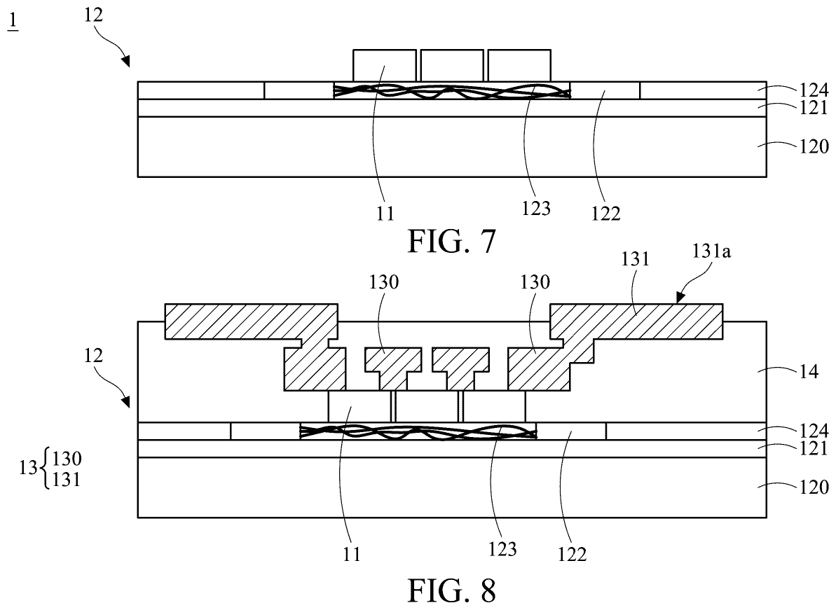

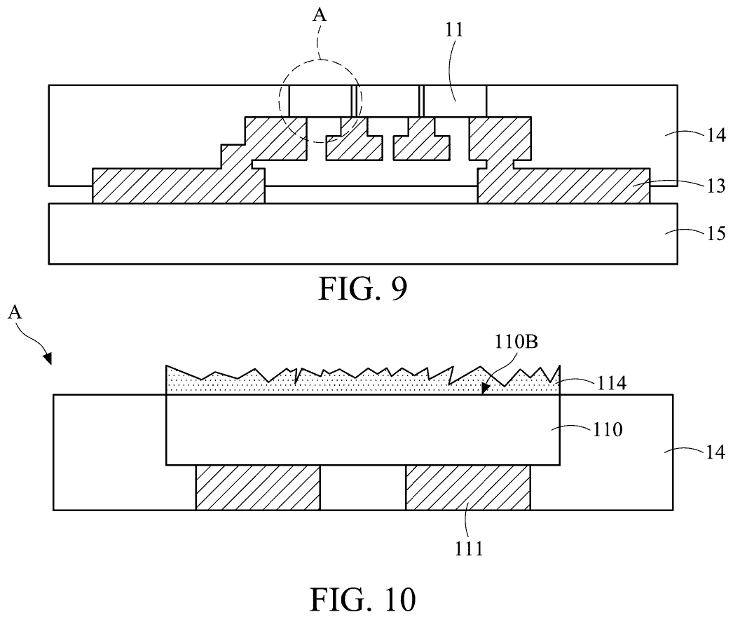

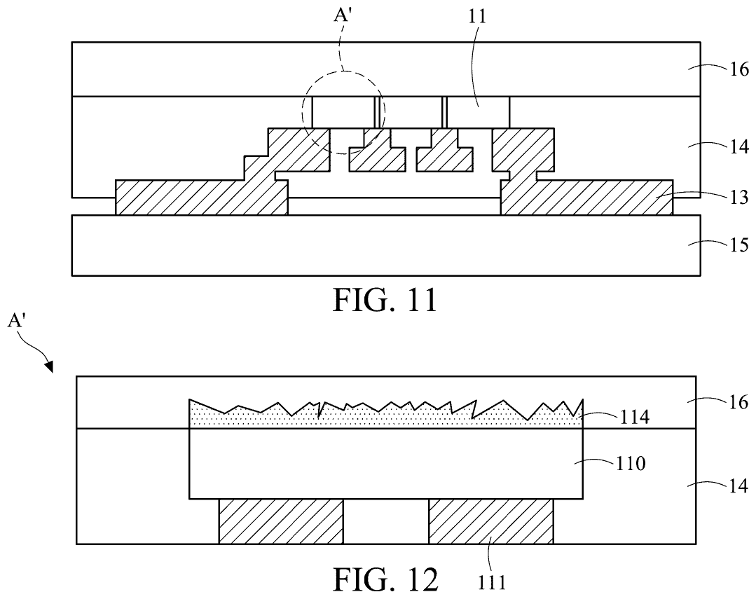

In the above, the semiconductor component 1 applicable to a semiconductor device has been described. Next, in the following, the semiconductor device 2 that may be formed using the semiconductor component 1 is provided. FIGS. 7. 8, 9, 11 and 13 are cross-sectional views of the semiconductor device 2 at different stages of the formation method according to some embodiments of the present disclosure, and FIGS. 10 and 12 are enlarged schematic views of the area A in FIG. 9 and the area A′ in FIG. 11 respectively.

As shown in FIG. 7, the semiconductor component 1 is provided, wherein the semiconductor component 1 includes the carrier 12 and the semiconductor element 11 disposed on the carrier 12. Specifically, the carrier 12 includes the second substrate 120, the adhesive layer 121, the photoresist layer 122, the bracket structure 123, and the cover layer 124. It should be noted that the elements or components in FIG. 7 may be similar or the same as the elements or components in FIG. 6. In the case that the details about these elements or components are only different in quantity, size, and proportion, the description may be referred to above and omitted here.

As shown in FIG. 8, following the above steps, an electrical connection component 13 and an insulating layer 14 are provided on the semiconductor component 1. In some embodiments, the electrical connection component 13 may include a connection part 130 and an electrode pad 131. The connection part 130 is located between the semiconductor element 11 and the electrode pad 131 and is electrically connected to the electrodes 111 of the semiconductor element 11. The electrode pad 131 includes the joint surfaces 131a and is used to electrically connect the semiconductor element 11 to an external power source. The connection part 130 is used to electrically connect the electrode pad 131 to the semiconductor element 11 and/or used to electrically connect the semiconductor elements 11 to each other. In some embodiments, the electrical connection component 13 may be used as a redistribution layer, which may extend the electrical contacts of the semiconductor element 11 (i.e., the electrodes 111) to a predetermined position (i.e., the electrode pads 131). In addition, due to the joint area of the electrode pads 131 being larger than the joint area of electrodes 111, the range of electrical connection with the outside is also extended, which is beneficial to the subsequent application of the semiconductor devices. It should be noted that in some embodiments, before the electrical connection component 13 is electrically connected to the electrodes 111 of the semiconductor element 11, the protective layer 112 may be removed through an etching process to expose the electrodes 111 of the semiconductor element 11. In some embodiments, the etching process may include dry etching (e.g., reactive-ion etching (RIE), inductively coupled plasma (ICP)), wet etching, and/or other etching method.

In some embodiments, the electrical connection component 13 includes a plurality of connecting parts 130 and a plurality of electrode pads 131, and the number of connecting parts 130 may be greater than or equal to the number of electrode pads 131. When there is a plurality of semiconductor elements 11 and they are electrically independent of each other, the plurality of semiconductor elements 11 are connected to different connecting parts 130 and electrode pads 131, and the number of the connecting parts 130 and electrode pads 131 is the equal to the number of the electrodes 111 of the semiconductor elements 11. Since the semiconductor elements 11 are electrically independent of each other, they may be controlled separately. When there is a plurality of semiconductor elements 11 and they are electrically connected to each other (e.g., connected in series or parallel), at least two adjacent semiconductor elements 11 are connected to the same one of the connecting parts 130 and are respectively connected to the corresponding electrode pads 131 through other corresponding connecting parts 130, thus reducing the number of connecting parts 130 and electrode pads 131. Therefore, the design of the circuit is simplified and the complexity of subsequent electrical connections to the outside is reduced.

In some embodiments, the electrical connection component 13 may include electrically conductive material. For example, the conductive material may include metals, conductive compounds, other suitable conductive materials, or a combination thereof, but the present disclosure is not limited thereto. In some embodiments, the metals may be tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (AI), molybdenum (M o), titanium (Ti), magnesium (M g), zinc (Zn), alloys thereof, or a combination thereof, but the present disclosure is not limited thereto. In some embodiments, the conductive compounds may include indium tin oxide (ITO), antimony zinc oxide (AZO), tin oxide (SnO), zinc oxide (ZnO), indium zinc oxide (IZO), indium gallium zinc oxide (IGZO), indium tin zinc oxide (ITZO), antimony tin oxide (ATO), titanic nitride (TiN), other suitable conductive compounds, or a combination thereof, but the present disclosure is not limited thereto. In some embodiments, the material of the connection parts 130 may be similar or the same as the material of the electrode pad 131 to reduce some defects that may exist at the two-phase interface.

In some embodiments, the insulating layer 14 is disposed on the carrier 12. Specifically, the insulating layer 14 covers the carrier 12, the semiconductor element 11, and the electrical connection component 13 and exposes the joint surfaces 131a of the electrode pads 131. In some embodiments, the insulating layer 14 may include silicon oxide (SiOₓ), silicon nitride (SiNₓ), silicon oxynitride (SiONₓ), fluorine-doped silicate glass (FSG), epoxy, polyimide (PI), polybenzoxazole (PBO), silicon, a combination thereof, and/or other suitable materials. In some embodiments, a surface of the insulating layer 14 is co-planar with the second surface 110B of the semiconductor stack 110 of the semiconductor element 11.

As shown in FIGS. 9 and 10, following the above steps, the semiconductor component 1, the electrical connection component 13, and the insulating layer 14 are turned over, and the carrier 12 is removed. Specifically, the semiconductor component 1, the electrical connection component 13, and the insulating layer 14 are turned over first, and then the joint surfaces 131a of the electrode pads 131 are joined to a third substrate 15. Finally, the carrier 12 is removed. In some embodiments, the third substrate 15 may be joined to the joint surfaces 131a of the electrode pads 131 first, and then the semiconductor component 1, the electrical connection component 13, the insulating layer, 14 and the third substrate 15 may be turned over, and after that, the carrier 12 is removed. For example, the carrier 12 may be removed by laser, irradiation, heating, other suitable methods, or a combination thereof. Removing the carrier 12 may expose the roughened structure 114 on the second surface 110B of the semiconductor stack 110, as shown in FIG. 10.

In some embodiments, following the above steps, when the semiconductor element 11 is a light-emitting element, the roughened structure 114 may be partially or completely removed to prevent the light emitted from the semiconductor element 11 is blocked by the roughened structure 114. For example, the roughened structure 114 on the center of the semiconductor stack 110 may be removed by a polishing process such as chemical mechanical polishing (CM P) and a portion of the roughened structure 114 located on the periphery of the second surface 110B of the semiconductor stack 110 may be remained to form an enclosed shape. Alternatively, the roughened structure 114 may be thinned by a grinding process such as chemical mechanical polishing, and the thickness of the roughened structure 114 may be reduced to a level that does not affect light penetration. It should be noted that when the semiconductor element 11 is not a light-emitting element, or the roughened structure 114 is nearly completely transparent, the above steps may be omitted.

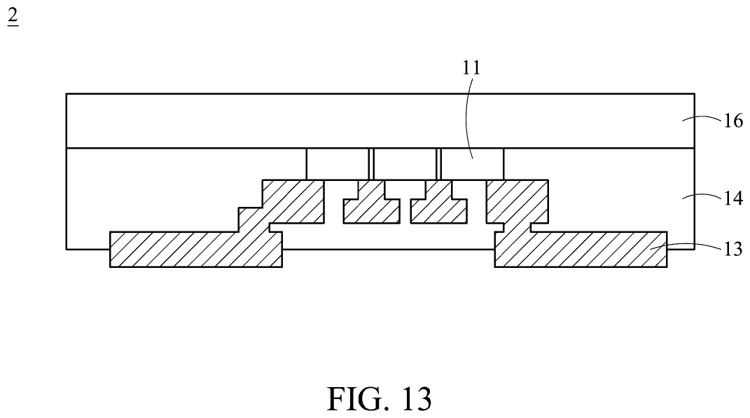

As shown in FIGS. 11, 12, and 13, following the above steps, a light-transmitting layer 16 is disposed on the insulating layer 14, and the third substrate 15 is removed to form a semiconductor device 2. Specifically, the light-transmitting layer 16 covers the insulating layer 14 and the exposed roughened structure 114 of the semiconductor element 11 to protect the second surface 110B of the semiconductor element 11 (e.g., as a light-emitting surface) from erosion of moisture, dust, or impurity. The third substrate 15 is removed to expose the joint surfaces 131a of the electrode pads 131 as an electrical contact for the semiconductor device 2 to be electrically connected to the outside. In some embodiments, the material of the light-transmitting layer 16 may be or may include silicone, epoxy, the like, or a combination thereof, but the present disclosure is not limited thereto.

In summary, the present disclosure provides a semiconductor component and a semiconductor device. Through the bracket structure and roughened structure in the semiconductor element, the semiconductor element in the semiconductor component of the present disclosure has excellent connection effect, thereby greatly improving the yield of the mass transfer process. In subsequent applications, these semiconductor components may be formed into various semiconductor devices, thereby being used in the fields of various electronic devices.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor component, comprising:
a carrier comprising a substrate and a bracket structure, wherein the bracket structure is disposed on the substrate;
a semiconductor element disposed on the carrier, wherein the semiconductor element comprises:
a semiconductor stack having a first surface and a second surface opposite each other;
a plurality of electrodes disposed on the first surface; and
a roughened structure disposed on the second surface and in direct contact with the bracket structure; and
a protective layer disposed on the first surface and covering the plurality of electrodes.

2. The semiconductor component as claimed in claim 1, wherein a material of the bracket structure comprises a biodegradable polymer.

3. The semiconductor component as claimed in claim 2, wherein the material of the bracket structure comprises at least one of polyglycolic acid (PGA), poly-L-lactic acid (PLLA), and poly(lactic-co-glycolic acid (PLGA).

4. The semiconductor component as claimed in claim 1, wherein a shape of the bracket structure comprises at least one of a fiber shape and a chain shape.

5. The semiconductor component as claimed in claim 1, wherein the semiconductor element is a light-emitting element, and the roughened structure is penetrated by a light emitted by the light-emitting element.

6. The semiconductor component as claimed in claim 1, wherein the roughened structure comprises a plurality of sharp protrusions, and the plurality of sharp protrusions protrude in a direction away from the second surface.

7. The semiconductor component as claimed in claim 6, wherein the plurality of sharp protrusions comprise a plurality of hooks.

8. The semiconductor component as claimed in claim 1, wherein a thickness of the roughened structure is between 100 nm and 1000 nm.

9. The semiconductor component as claimed in claim 1, wherein the roughened structure comprises tin (Sn).

10. The semiconductor component as claimed in claim 1, wherein the carrier further comprises a cover layer, and the cover layer is disposed on the substrate and covers the bracket structure.

11. The semiconductor component as claimed in claim 10, wherein the cover layer comprises silicone.

12. The semiconductor component as claimed in claim 10, wherein a hardness of the cover layer is less than a hardness of the roughened structure.

13. The semiconductor component as claimed in claim 10, wherein the carrier further comprises a photoresist layer surrounding the cover layer and the bracket structure.

14. The semiconductor component as claimed in claim 13, wherein a thickness of the photoresist layer is between 100 nm and 2000 nm.

15. A semiconductor device, comprising:
an electrical connection component;
a semiconductor element disposed on the electrical connection component, wherein the semiconductor element comprises:
a semiconductor stack having a first surface and a second surface opposite each other, wherein the first surface faces the electrical connection component;
a plurality of electrodes disposed on the first surface and electrically connected to the electrical connection component; and
a roughened structure disposed on the second surface;
an insulating layer covering the semiconductor element and the electrical connection component, and exposing the roughened structure of the semiconductor element and a joint surface of the electrical connection component; and
a light-transmitting layer disposed on the insulating layer and covering the insulating layer and the exposed roughened structure.

16. The semiconductor device as claimed in claim 15, wherein the electrical connection component comprises a plurality of connection parts and a plurality of electrode pads, the plurality of connection parts are between the semiconductor element and the plurality of electrode pads, and the semiconductor element is electrically connected to the plurality of electrode pads by the plurality of connecting parts.

17. The semiconductor device as claimed in claim 15, wherein the semiconductor element is a light-emitting element, and the roughened structure is penetrated by a light emitted by the light-emitting element.

18. The semiconductor device as claimed in claim 15, wherein a surface of the insulating layer is co-planar with the second surface of the semiconductor stack of the semiconductor element.

19. The semiconductor device as claimed in claim 15, wherein the insulating layer comprises at least one of silicon oxide (SiOₓ), silicon nitride (SiNₓ), silicon oxynitride (SiONₓ), fluorine-doped silicate glass (FSG), epoxy, polyimide (PI), polybenzoxazole (PBO), and silicon.

20. The semiconductor device as claimed in claim 15, wherein the light-transmitting layer comprises at least one of silicone and epoxy.
